(19) United States
(12) Patent Application Publication
(10) Pub. No.: US 2024/0304622 A1
(43) Pub. Date: Sep. 12, 2024

(54) SEMICONDUCTOR DEVICE INCLUDING TWO-DIMENSIONAL MATERIAL AND METHOD OF MANUFACTURING THE SAME

(71) Applicants: Samsung Electronics Co., Ltd., Suwon-si (KR); THE UNIVERSITY OF CHICAGO, Chicago, IL (US)

(72) Inventors: Minsu SEOL, Suwon-si (KR); Ce LIANG, Chicago, IL (US); Jiwoong PARK, Chicago, IL (US); Kyung-Eun BYUN, Suwon-si (KR); Changhyun KIM, Suwon-si (KR)

(73) Assignees: Samsung Electronics Co., Ltd., Suwon-si (KR); THE UNIVERSITY OF CHICAGO, Chicago, IL (US)

(21) Appl. No.: 18/416,403

(22) Filed: Jan. 18, 2024

Related U.S. Application Data
(60) Provisional application No. 63/450,167, filed on Mar. 6, 2023.

(30) Foreign Application Priority Data
Mar. 29, 2023 (KR) 10-2023-0041499

(51) Int. Cl. H01L 27/092; H01L 21/02; H01L 21/8256; H01L 29/24; H01L 29/66; H01L 29/76

(52) U.S. Cl. CPC H01L 27/092; H01L 21/02568; H01L 21/8256; H01L 29/24; H01L 29/66969; H01L 29/7606

(57) ABSTRACT

Provided are a semiconductor device including a two-dimensional material and a method of manufacturing the semiconductor device. The semiconductor device may include a substrate, first and second two-dimensional material layers on the substrate and junctioned to each other in a lateral direction to form a coherent interface, a first source electrode and a first drain electrode on the first two-dimensional material layer, a first gate electrode between the first source electrode and the first drain electrode, a second source electrode and a second drain electrode on the second two-dimensional material layer, and a second gate electrode between the second source electrode and the second drain electrode.

### CROSS-REFERENCE TO RELATED APPLICATION

This application is based on and claims the benefit of U.S. Provisional Patent Application No. 63/450,167, filed on Mar. 6, 2023, in the United States Patent and Trademark Office, and claims priority under 35 U.S.C. § 119 to Korean Patent Application No. 10-2023-0041499, filed on Mar. 29, 2023, in the Korean Intellectual Property Office, the disclosures of each of which are incorporated by reference herein in their entirety.

### BACKGROUND

### 1.Field

The disclosure relates to a semiconductor device including a two-dimensional material and a method of manufacturing the semiconductor device.

### 2. Description of the Related Art

Transistors are semiconductor devices for performing electrical switching and have been used in various semiconductor products such as memories and driving ICs. Because the number of semiconductor devices that can be integrated on one wafer increases and the driving speed of semiconductor devices increases when the size of semiconductor devices decreases, research has been actively conducted to reduce the size of semiconductor devices.

Recently, research has been conducted to use two-dimensional materials as a way to reduce the size of semiconductor devices. Because the two-dimensional materials have stable and excellent characteristics even with a small thickness of 1 nm or less, they have been spotlighted as materials capable of overcoming the limitation of performance degradation due to a decrease in the size of semiconductor devices.

### SUMMARY

Provided are a semiconductor device including a two-dimensional material and a method of manufacturing the semiconductor device.

Additional aspects will be set forth in part in the description which follows and, in part, will be apparent from the description, or may be learned by practice of the presented embodiments of the disclosure.

According to an example embodiment, a semiconductor device may include a substrate; a first two-dimensional material layer and a second two-dimensional material layer on the substrate, the first two-dimensional material layer and the second two-dimensional material layer being junctioned to each other in a lateral direction to form a coherent interface; a first source electrode and a first drain electrode on the first two-dimensional material layer; a first gate electrode between the first source electrode and the first drain electrode; a second source electrode and a second drain electrode on the second two-dimensional material layer; and a second gate electrode between the second source electrode and the second drain electrode.

In some embodiments, the first two-dimensional material layer and the second two-dimensional material layer have monocrystalline structures with a same crystal orientation, and

In some embodiments, a material of the first two-dimensional material layer may be different than a material of the second two-dimensional material layer.

In some embodiments, a lattice constant difference between a material of the first two-dimensional material layer and a material of the second two-dimensional material layer may be 10% or less.

In some embodiments, a semiconductor material of the first two-dimensional material layer and a semiconductor material of the second two-dimensional material layer each may have a bandgap of about 0.1 eV to about 3.0 eV.

In some embodiments, the first two-dimensional material layer and the second two-dimensional material layer each independently may include transition metal dichalcogenide (TMD), black phosphorus, or graphene.

In some embodiments, the first two-dimensional material layer, the second two-dimensional material layer, or both the first two-dimensional material layer and the second two-dimensional material layer may include the TMD. The TMD may include a metal element and a chalcogen element. The metal element may include one of Mo, W, Nb, V, Ta, Ti, Zr, Hf, Tc, and Re. The chalcogen element may include one of S, Se, and Te.

In some embodiments, the first two-dimensional material layer and the second two-dimensional material layer each may include about 1 layer to about 10 layers.

In some embodiments, the semiconductor device may further include a first gate insulating layer between the first two-dimensional material layer and the first gate electrode; and a second gate insulating layer between the second two-dimensional material layer and the second gate electrode.

In some embodiments, a first one of the first two-dimensional material layer and the second two-dimensional material layer may include an n-type semiconductor material, and a second one of the first two-dimensional material layer and second two-dimensional material layer may include a p-type semiconductor material.

In some embodiments, the first two-dimensional material layer, the second two-dimensional material layer, the first source electrode, the first drain electrode, the second source electrode, the second drain electrode, the first gate electrode, and the second gate electrode may be parts of a complementary metal-oxide-semiconductor (CMOS) inverter.

In some embodiments, the first drain electrode and the second drain electrode may be integrally formed to provide a common drain electrode.

In some embodiments, the common drain electrode may be on a junction area between the first two-dimensional material layer and the second two-dimensional material layer.

In some embodiments, the first gate electrode and the second gate electrode may be electrically connected to each other.

In some embodiments, the first gate electrode and the second gate electrodes are integrally formed to constitute a common gate electrode.

According to an example embodiment, a method of manufacturing a semiconductor device may include forming a first two-dimensional material layer by depositing a first two-dimensional material on a substrate and patterning the first two-dimensional material; forming a second two-dimensional material layer by lateral-epitaxial-growing a second two-dimensional material at a patterned edge of the first two-dimensional material layer, the second two-dimensional material layer forming a coherent interface with the first two-dimensional material layer, the first two-dimensional material layer and the second two-dimensional material layer each having a monocrystalline structure; forming a first source electrode and a first drain electrode on the first two-dimensional material layer; forming a first gate electrode between the first source electrode and the first drain electrode; forming a second source electrode and a second drain electrode on the second two-dimensional material layer; and forming a second gate electrode between the second source electrode and the second drain electrode.

In some embodiments, the first two-dimensional material layer and the second two-dimensional material layer each independently may include transition metal dichalcogenide (TMD), black phosphorus, or graphene.

In some embodiments, a first one of the first two-dimensional material layer and the second two-dimensional material layer may include an n-type semiconductor material, and a second one of the first two-dimensional material layer and the second two-dimensional material layer may include an p-type semiconductor material.

In some embodiments, the first drain electrode and the second drain electrode may be integrally formed to constitute a common drain electrode.

In some embodiments, the common drain electrode may be formed on a junction area between the first two-dimensional material layer and the second two-dimensional material layer.

In some embodiments, the first gate electrode and the second gate electrode may be integrally formed to constitute a common gate electrode.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view illustrating a semiconductor device according to an embodiment;

FIG. 2 is a cross-sectional view taken along line I-I′ of FIG. 1;

FIGS. 3A to 3D illustrate a method of manufacturing a semiconductor device, according to an embodiment;

FIG. 4 illustrates a BF-TEM image, a DF-TEM image, and an SAED pattern image of a WS₂ layer connected to and grown on a side surface of a patterned MoS₂ layer;

FIG. 5 is a perspective view illustrating a semiconductor device according to another embodiment;

FIGS. 6A to 6D illustrate a method of manufacturing a semiconductor, device according to an embodiment;

FIG. 7 is a perspective view illustrating a semiconductor device according to another embodiment;

FIG. 8 is a perspective view illustrating a semiconductor device according to another embodiment;

FIG. 9 is a cross-sectional view taken along line II-II′ of FIG. 8;

FIG. 10 is a perspective view illustrating a semiconductor device according to another embodiment;

FIG. 11 is a cross-sectional view taken along line III-III′ of FIG. 10; and

FIG. 12 is a block diagram of an electronic system including an semiconductor device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, embodiments will be described in detail with reference to the accompanying drawings. Like reference numerals in the drawings will denote like elements, and sizes of elements in the drawings may be exaggerated for clarity and convenience of description. The embodiments described below are merely examples, and various modifications may be made therein.

As used herein, the terms “over” or “on” may include not only “directly over” or “directly on” but also “indirectly over” or “indirectly on”. As used herein, the singular forms “a”, “an”, and “the” are intended to include the plural forms as well, unless the context clearly indicates otherwise. Also, when something is referred to as “including” a component, another component may be further included unless specified otherwise.

The use of the terms “a”, “an”, and “the” and other similar indicative terms may be construed to cover both the singular and the plural. Unless there is an explicit order or description to the contrary, operations constituting a method may be performed in a suitable order and are not necessarily limited to the described order.

Also, as used herein, the terms “units” and “modules” may refer to units that perform at least one function or operation, and the units may be implemented as hardware or software or a combination of hardware and software.

Connections or connection members of lines between the elements illustrated in the drawings may illustratively represent functional connections and/or physical or logical connections and may be represented as various replaceable or additional functional connections, physical connections, or logical connections in an actual apparatus.

All examples or illustrative terms used herein are merely intended to describe the technical concept of the disclosure in detail, and the scope of the disclosure is not limited by these examples or illustrative terms unless otherwise defined in the appended claims.

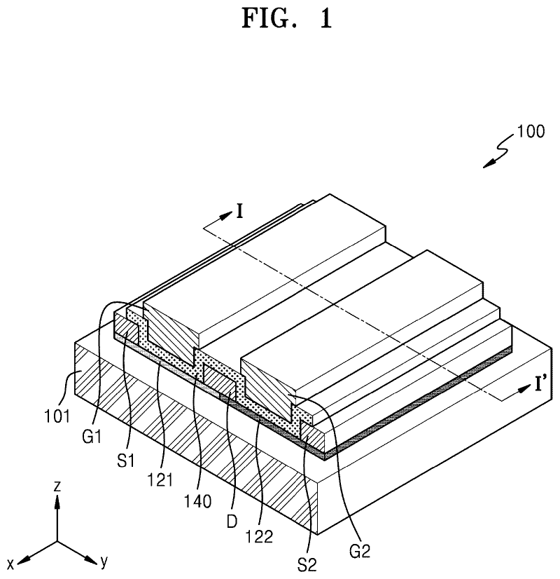

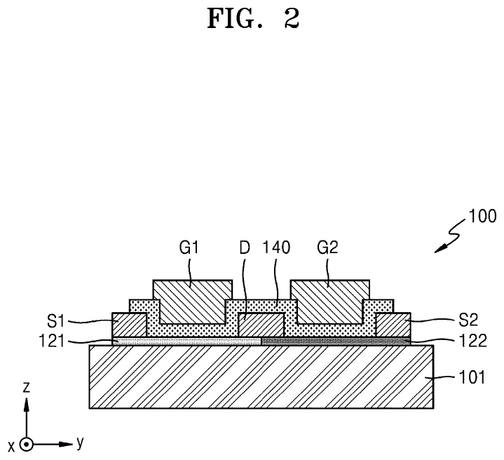

FIG. 1 is a perspective view illustrating a semiconductor device 100 according to an embodiment. The semiconductor device 100 illustrated in FIG. 1 may include, for example, a complementary metal-oxide-semiconductor (CMOS) inverter. FIG. 2 is a cross-sectional view taken along line I-I′ of FIG. 1.

Referring to FIGS. 1 and 2, first and second two-dimensional material layers 121 and 122 junctioned to each other may be arranged on a substrate 101. The substrate 101 may include various materials. For example, the substrate 101 may include a monocrystalline silicon substrate, a compound semiconductor substrate, or an SOI substrate; however, this is merely an example. Also, the substrate 101 may further include, for example, a doped area, an electronic element such as a transistor, or a peripheral circuit for selecting and controlling memory cells storing data.

The first and second two-dimensional material layers 121 and 122 may be arranged parallel to the surface of the substrate 101. The first and second two-dimensional material layers 121 and 122 may be hetero-junctioned to each other in the lateral direction to form a coherent interface therebetween. Here, the junction interface between the first and second two-dimensional material layers 121 and 122 may be parallel to a certain direction (x-axis direction). Each of the first and second two-dimensional material layers 121 and 122 may include a two-dimensional material having semiconductor characteristics. The two-dimensional material may refer to a material having a layered structure in which constituent atoms are two-dimensionally coupled to each other. The two-dimensional material having semiconductor characteristics may have excellent electrical properties and may maintain high mobility without significantly changing its characteristics even when its thickness decreases to the nanoscale.

As described below, the first two-dimensional material layer 121 may be formed by growing a first two-dimensional material on the surface of the substrate 101 and then patterning the first two-dimensional material. Here, the first two-dimensional material constituting the first two-dimensional material layer 121 may include a monocrystalline structure having a certain crystal orientation. The second two-dimensional material layer 122 may be formed by lateral-epitaxial-growing a second two-dimensional material from a patterned edge of the first two-dimensional material layer 121. Here, the second two-dimensional material may have a lattice constant similar to a lattice constant of the first two-dimensional material. For example, a lattice constant difference between the first two-dimensional material and the second two-dimensional material may be about 10% or less. The second two-dimensional material constituting the second two-dimensional material layer 122 may include a monocrystalline structure having the same crystal orientation as the first two-dimensional material. Accordingly, the first two-dimensional material layer 121 and the second two-dimensional material layer 122 may be junctioned to each other to form a coherent interface having almost no defects.

Each of the first and second two-dimensional material layers 121 and 122 may include a material having a bandgap of about 0.1 eV to about 3.0 eV. Each of the first and second two-dimensional material layers 121 and 122 may include transition metal dichalcogenide (TMD), black phosphorus, or graphene. However, the disclosure is not limited thereto.

The TMD may be a two-dimensional material having semiconductor characteristics and may be a compound of a transition metal and a chalcogen element.

Here, the transition metal may include, for example, at least one of Mo, W, Nb, V, Ta, Ti, Zr, Hf, Co, Tc, and Re, and the chalcogen element may include, for example, at least one of S, Se, and Te. As a particular example, the TMD may include MoS₂, MoSe₂, MoTe₂, WS₂, WSe₂, WTe₂, ZrS₂, ZrSe₂, HfS₂, HfSe₂, NbSe₂, ReSe₂, or the like.

The first and second two-dimensional material layers 121 and 122 may include semiconductor materials having different polarities. For example, the first two-dimensional material layer 121 may include an n-type semiconductor material, and the second two-dimensional material layer 122 may include a p-type semiconductor material. As a particular example, the first two-dimensional material layer 121 may include MoS₂, and the second two-dimensional material layer 122 may include WSe₂.

The first two-dimensional material layer 121 may be doped with an n-type dopant, and the second two-dimensional material layer 122 may be doped with a p-type dopant. The p-type dopant or the n-type dopant may be doped by using ion implantation or chemical doping.

A source of the n-type dopant may include, for example, a reduction product of a substituted or unsubstituted nicotinamide; a reduction product of a compound which is chemically bound to a substituted or unsubstituted nicotinamide; and a compound including at least two pyridinium moieties in which a nitrogen atom of at least one of the pyridinium moieties is reduced. For example, the source of the n-type dopant may include nicotinamide mononucleotide-H (NMNH), nicotinamide adenine dinucleotide-H (NADH), or nicotinamide adenine dinucleotide phosphate-H (NADPH) or may include viologen. Alternatively, the source of the n-type dopant may include a polymer such as polyethylenimine (PEI). Alternatively, the n-type dopant may include an alkali metal such as K or Li.

A source of the p-type dopant may include, for example, an ionic liquid such as NO₂BF₄, NOBF₄, or NO₂SbF₆; an acidic compound such as HCl, H₂PO₄, CH₃ COOH, H₂SO₄, or HNO₃; or an organic compound such as dichlorodicyanoquinone (DDQ), oxone, dimyristoylphosphatidylinositol (DMPI), or trifluoromethanesulfoneimide.

Alternatively, the source of the p-type dopant may include HPtCl₄, AuCl₃, HAuCl₄, silver trifluoromethanesulfonate (AgOTf), AgNO₃, HPdCl₆, Pd (OAc)₂, Cu (CN)₂, or the like. Moreover, the p-type dopant and n-type dopant materials described above are merely examples, and various other materials may be used as dopants.

A case where the first two-dimensional material layer 121 includes an n-type semiconductor material and the second two-dimensional material layer 122 includes a p-type semiconductor material has been described above; however, the disclosure is not limited thereto, and the first two-dimensional material layer 121 may include a p-type semiconductor material and the second two-dimensional material layer 122 may include an n-type semiconductor material.

Each of the first and second two-dimensional material layers 121 and 122 may have a monolayer or multilayer structure, and each layer may have an atomic-level thickness. Each of the first and second two-dimensional material layers 121 and 122 may include, for example, about 1 layer to about 10 layers (e.g., about 1 layer to about 5 layers); however, the disclosure is not limited thereto. The second two-dimensional material layer 122 may include the same number of layers as the first two-dimensional material layer 121; however, the disclosure is not limited thereto.

Each of the first and second two-dimensional material layers 121 and 122 may have a length in a first direction (y-axis direction) and a width in a second direction (x-axis direction). For example, the first and second two-dimensional material layers 121 and 122 may have the same length and width. However, the disclosure is not limited thereto, and the first and second two-dimensional material layers 121 and 122 may be configured such that at least one of lengths and widths thereof are different from each other.

A first source electrode S1 and a drain electrode D may be arranged on both sides of the first two-dimensional material layer 121, and a second source electrode S2 and a drain electrode D may be arranged on both sides of the second two-dimensional material layer 122. Here, the drain electrode D may be a common drain electrode and may be arranged in a junction area between the first and second two-dimensional material layers 121 and 122.

The first source electrode S1 and the drain electrode D may be arranged apart from each other in the longitudinal direction (y-axis direction) of the first two-dimensional material layer 121. The first two-dimensional material layer 121 may form a first channel between the first source electrode S1 and the drain electrode D. The second source electrode S2 and the drain electrode D may be arranged apart from each other in the longitudinal direction (y-axis direction) of the second two-dimensional material layer 122. The second two-dimensional material layer 122 may form a second channel between the second source electrode S2 and the drain electrode D. The first and second source electrodes S1 and S2 and the drain electrode D may include, for example, a metal material with excellent electrical conductivity such as Ag, Au, Pt, or Cu; however, the disclosure is not limited thereto.

A gate insulating layer 140 and a first gate electrode G1 may be sequentially arranged on the first two-dimensional material layer 121 between the first source electrode S1 and the drain electrode D. A gate insulating layer 140 and a second gate electrode G2 may be sequentially arranged on the second two-dimensional material layer 122 between the second source electrode S2 and the drain electrode D. The first and second gate electrodes G1 and G2 may be configured to be electrically connected to each other such that the same voltage may be applied thereto.

The gate insulating layer 140 may include a dielectric material such as, for example, a silicon nitride; however, the disclosure is not limited thereto. Each of the first and second gate electrodes G1 and G2 may include a metal material or a conductive oxide. Here, the metal material may include, for example, at least one selected from among Au, Ti, TiN, TaN, W, Mo, WN, Pt, and Ni. Also, the conductive oxide may include, for example, indium tin oxide (ITO) or indium zinc oxide (IZO). However, this is merely an example.

According to the present embodiments, because the first and second two-dimensional material layers 121 and 122 having a monocrystalline structure are hetero-junctioned to each other in the lateral direction to form a coherent interface, the degradation of electron transfer due to a grain boundary may be limited and/or prevented and thus the high-performance semiconductor device 100 may be implemented.

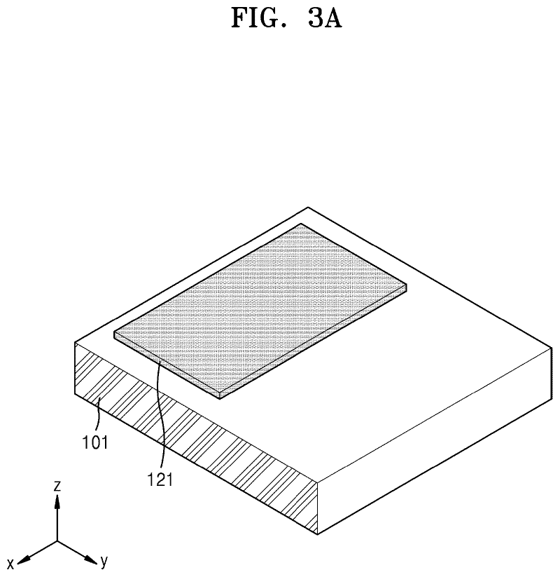

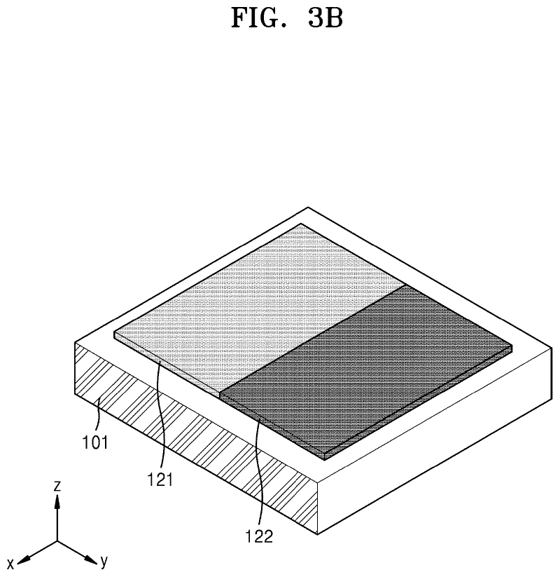

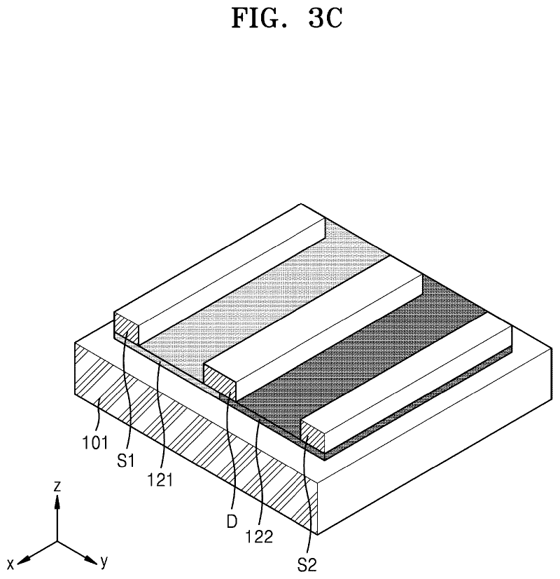

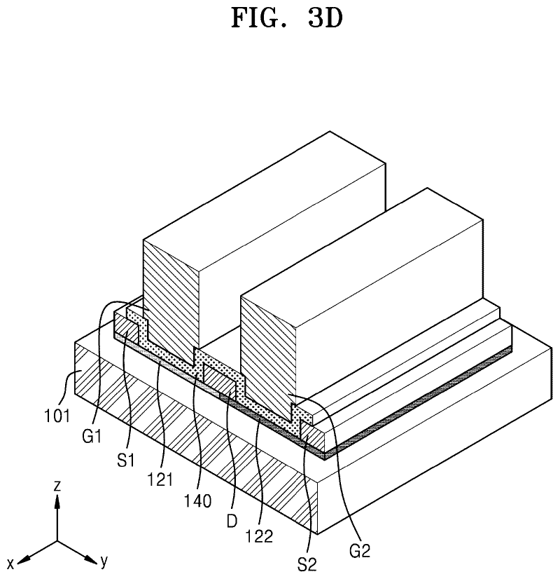

Hereinafter, a method of manufacturing the semiconductor device 100 described above will be described. FIGS. 3A to 3D illustrate a method of manufacturing the semiconductor device 100, according to an embodiment.

Referring to FIG. 3A, a first two-dimensional material layer 121 may be formed on the upper surface of a substrate 101. The substrate 101 may include various materials. For example, the substrate 101 may include a monocrystalline silicon substrate, a compound semiconductor substrate, or an SOI substrate; however, this is merely an example.

The first two-dimensional material layer 121 may be formed by growing a first two-dimensional material on the upper surface of the substrate 101 by using, for example, chemical vapor deposition (CVD) (e.g., metal-organic CVD (MOCVD)) and then patterning the first two-dimensional material into a certain shape. The first two-dimensional material layer 121 may have a length in the first direction (y-axis direction) and a width in the second direction (x-axis direction). The patterned first two-dimensional material forming the first two-dimensional material layer 121 may have a monocrystalline structure with a certain crystal orientation.

The first two-dimensional material may include a semiconductor material having a bandgap of about 0.1 eV to about 3.0 eV. For example, the first two-dimensional material may include TMD, black phosphorus, or graphene. The TMD may include a transition metal including, for example, at least one of Mo, W, Nb, V, Ta, Ti, Zr, Hf, Co, Tc, and Re and a chalcogen element including, for example, at least one of S, Se, and Te. As a particular example, the TMD may include MoS₂, MoSe₂, MoTe₂, WS₂, WSe₂, WTe₂, ZrS₂, ZrSe₂, HfS₂, HfSe₂, NbSe₂, ReSe₂, or the like. The first two-dimensional material layer 121 may include, for example, about 1 layer to about 10 layers (e.g., about 1 layer to about 5 layers); however, the disclosure is not limited thereto.

Referring to FIG. 3B, a second two-dimensional material layer 122 junctioned to the side surface of the first two-dimensional material layer 121 may be formed on the upper surface of the substrate 101. Here, the side surface of the first two-dimensional material layer 121 to which the second two-dimensional material layer 122 is junctioned may be parallel to the second direction (x-axis direction). The second two-dimensional material layer 122 may be formed by lateral-epitaxial-growing a second two-dimensional material from a patterned edge of the first two-dimensional material layer 121 by using CVD (e.g., MOCVD). An operation of patterning the second two-dimensional material into a certain shape after growing the second two-dimensional material may be further included. Here, the second two-dimensional material may have a lattice constant similar to a lattice constant of the first two-dimensional material. For example, a lattice constant difference between the first two-dimensional material and the second two-dimensional material may be about 10% or less. The second two-dimensional material may include a semiconductor material having a bandgap of about 0.1 eV to about 3.0 eV. For example, the second two-dimensional material may include TMD, black phosphorus, or graphene. The second two-dimensional material layer 122 may include, for example, about 1 layer to about 10 layers (e.g., about 1 layer to about 5 layers); however, the disclosure is not limited thereto.

By controlling growth conditions (e.g., the flow rate of a precursor material, the injection amount of the carrier gas, the reaction temperature, the pressure, and/or the like) in the growing process of the second two-dimensional material, the second two-dimensional material having the same crystal orientation as the first two-dimensional material may be grown on the side surface of the first two-dimensional material layer 121. The second two-dimensional material forming the second two-dimensional material layer 122 may include a monocrystalline structure having the same crystal orientation as the first two-dimensional material. Thus, the first two-dimensional material layer 121 and the second two-dimensional material layer 122 may be hetero-junctioned to each other to form a coherent interface having almost no defects.

The first and second two-dimensional material layers 121 and 122 may include semiconductor materials having different polarities. For example, the first two-dimensional material layer 121 may include an n-type semiconductor material, and the second two-dimensional material layer 122 may include a p-type semiconductor material. As a particular example, the first two-dimensional material layer 121 may include MoS₂, and the second two-dimensional material layer 122 may include WSe₂. Alternatively, the first two-dimensional material layer 121 may include a p-type semiconductor material, and the second two-dimensional material layer 122 may include an n-type semiconductor material.

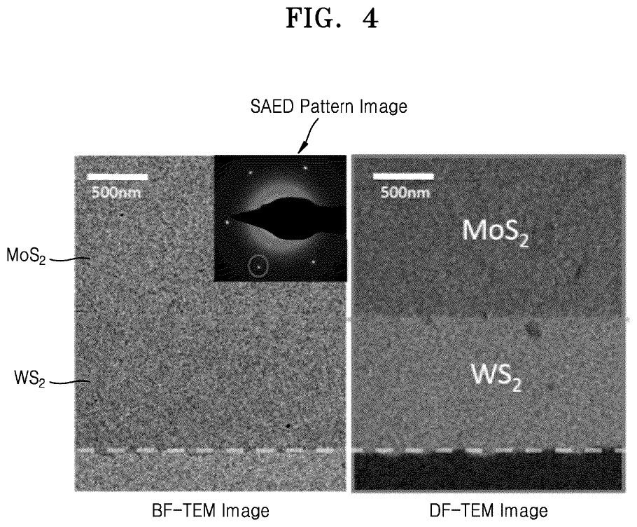

FIG. 4 illustrates a bright-field transmission electron microscopy (BF-TEM) image, a dark-field transmission electron microscopy (DF-TEM) image, and a selective area electron diffraction (SAED) pattern image of a WS₂ layer grown on a side surface of a patterned MoS₂ layer.

Referring to FIG. 4, a WS₂ layer is grown as a monolayer on the side surface of a patterned MoS₂ layer, and a monocrystalline SAED pattern is observed as the WS₂layer grows with the same crystal orientation as the MoS₂ layer.

FIG. 3B illustrates a case where the first and second two-dimensional material layers 121 and 122 are formed to have the same dimension (length and width). However, the first and second two-dimensional material layers 121 and 122 may be formed to have different dimensions according to the design conditions of the semiconductor device 100. For example, the first and second two-dimensional material layers 121 and 122 may be configured such that at least one of the lengths thereof in the first direction (y-axis direction) and the widths thereof in the second direction (x-axis direction) are different from each other.

Referring to FIG. 3C, a first source electrode S1, a second source electrode S2, and a drain electrode D may be formed on the first and second two-dimensional material layers 121 and 122. The first source electrode S1 may be formed on one side of the first two-dimensional material layer 121, and the second source electrode S2 may be formed on one side of the second two-dimensional material layer 122. Also, the drain electrode D may be a common drain electrode and may be formed on a junction area between the first and second two-dimensional material layers 121 and 122. The first source electrode S1 and the drain electrode D may be formed apart from each other in the longitudinal direction (y-axis direction) of the first two-dimensional material layer 121, and the second source electrode S2 and the drain electrode D may be formed apart from each other in the longitudinal direction (y-axis direction) of the second two-dimensional material layer 122. The first and second source electrodes S1 and S2 and the drain electrode D may include, for example, a metal material with excellent electrical conductivity such as Ag, Au, Pt, or Cu; however, the disclosure is not limited thereto.

Referring to FIG. 3D, a gate insulating layer 140 may be formed to cover the first and second source electrodes S1 and S2, the drain electrode D, and the first and second two-dimensional material layers 121 and 122. Also, a first gate electrode G1 may be formed on the gate insulating layer 140 between the first source electrode S1 and the drain electrode D, and a second gate electrode G2 may be formed on the gate insulating layer 140 between the second source electrode S2 and the drain electrode D.

The gate insulating layer 140 may include, for example, a silicon nitride; however, the disclosure is not limited thereto. Each of the first and second gate electrodes G1 and G2 may include a metal material or a conductive oxide. Here, the metal material may include, for example, at least one selected from among Au, Ti, TiN, TaN, W, Mo, WN, Pt, and Ni. Also, the conductive oxide may include, for example, indium tin oxide (ITO) or indium zinc oxide (IZO). However, this is merely an example.

A case where two different first and second two-dimensional material layers 121 and 122 are hetero-junctioned to each other in the lateral direction to form a coherent interface has been described above. However, the disclosure is not limited thereto, and a plurality of first two-dimensional material layers 121 and a plurality of second two-dimensional material layers 122 may be alternately hetero-junctioned to each other form a coherent interface therebetween, and in this case, a semiconductor device array may be implemented. Also, three or more different two-dimensional material layers may be hetero-junctioned to each other in the lateral direction to form a coherent interface therebetween. For example, a third two-dimensional material layer (not illustrated) between the first and second two-dimensional material layers 121 and 122 may be hetero-junctioned to the first and second two-dimensional material layers 121 and 122 in the lateral direction to form a coherent interface therebetween. As a particular example, in order to minimize an interface defect, a WS₂ buffer layer may be inserted between a MoS₂ layer including an n-type two-dimensional material and a WSe₂ layer including a p-type two-dimensional material.

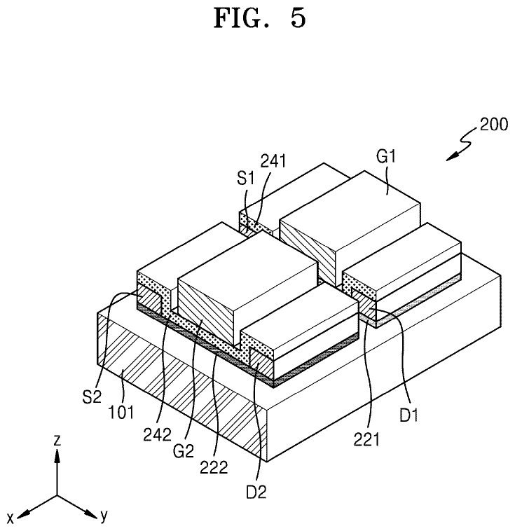

FIG. 5 is a perspective view illustrating a semiconductor device 200 according to another embodiment. The semiconductor device 200 illustrated in FIG. 5 may include a CMOS device. Hereinafter, differences from the above embodiments will be mainly described.

Referring to FIG. 5, on a substrate 101, first and second two-dimensional material layers 221 and 222 may be arranged apart from each other in a certain direction (x-axis direction). The first and second two-dimensional material layers 221 and 222 may be arranged parallel to the surface of the substrate 101.

The first two-dimensional material layer 221 may include a first two-dimensional material having a monocrystalline structure having a certain crystal orientation, and the second two-dimensional material layer 222 may include a second two-dimensional material having a monocrystalline structure having the same crystal orientation as the first two-dimensional material.

As described below, the first two-dimensional material layer 221 may be formed by growing a first two-dimensional material on the surface of the substrate 101 and then patterning the first two-dimensional material. The second two-dimensional material layer 222 may be formed by lateral-epitaxial-growing a second two-dimensional material from a patterned edge of the first two-dimensional material layer 221. Here, the second two-dimensional material may include a monocrystalline structure having the same crystal orientation as the first two-dimensional material.

Accordingly, the first two-dimensional material layer 221 and the second two-dimensional material layer 222 may be junctioned to each other to form a coherent interface having almost no defects. Subsequently, by removing the junction area between the first and second two-dimensional material layers 221 and 222 by patterning, first and second two-dimensional material layers 221 and 222 spaced apart from each other and having a monocrystalline structure with the same crystal orientation may be formed on the surface of the substrate 101.

Each of the first and second two-dimensional material layers 221 and 222 may include a material having a bandgap of about 0.1 eV to about 3.0 eV. For example, each of the first and second two-dimensional material layers 221 and 222 may include TMD, black phosphorus, or graphene; however, the disclosure is not limited thereto. The first and second two-dimensional material layers 221 and 222 may include semiconductor materials having different polarities. For example, the first two-dimensional material layer 221 may include an n-type semiconductor material, and the second two-dimensional material layer 222 may include a p-type semiconductor material. Also, the first two-dimensional material layer 221 may include a p-type semiconductor material, and the second two-dimensional material layer 222 may include an n-type semiconductor material. Each of the first and second two-dimensional material layers 221 and 222 may have a monolayer or multilayer structure. The second two-dimensional material layer 222 may include the same number of layers as the first two-dimensional material layer 221; however, the disclosure is not limited thereto.

Each of the first and second two-dimensional material layers 221 and 222 may have a length in a first direction (y-axis direction) and a width in a second direction (x-axis direction). For example, the first and second two-dimensional material layers 221 and 222 may have the same length and width. However, the disclosure is not limited thereto, and the first and second two-dimensional material layers 221 and 222 may be configured such that at least one of lengths and widths thereof are different from each other.

A first source electrode S1 and a first drain electrode D1 may be arranged on both sides of the first two-dimensional material layer 221, and a second source electrode S2 and a second drain electrode D2 may be arranged on both sides of the second two-dimensional material layer 222. The first source electrode S1 and the first drain electrode D1 may be arranged apart from each other in the longitudinal direction (y-axis direction) of the first two-dimensional material layer 221. The first two-dimensional material layer 221 may form a first channel between the first source electrode S1 and the first drain electrode D1. The second source electrode S2 and the second drain electrode D2 may be arranged apart from each other in the longitudinal direction (y-axis direction) of the second two-dimensional material layer 222. The second two-dimensional material layer 222 may form a second channel between the second source electrode S2 and the second drain electrode D2.

A first gate insulating layer 241 and a first gate electrode G1 may be sequentially arranged on the first two-dimensional material layer 221 between the first source electrode S1 and the first drain electrode D1. Also, a second gate insulating layer 242 and a second gate electrode G2 may be sequentially arranged on the second two-dimensional material layer 222 between the second source electrode S2 and the second drain electrode D2.

For example, when the first two-dimensional material layer 221 includes a p-type semiconductor material, the first two-dimensional material layer 221, the first source electrode S1, the first drain electrode D1, and the first gate electrode G1 may constitute a PMOS. Also, when the second two-dimensional material layer 222 includes an n-type semiconductor material, the second two-dimensional material layer 222, the second source electrode S2, the second drain electrode D2, and the second gate electrode G2 may constitute an NMOS. Moreover, a case where the first and second two-dimensional material layers 221 and 222 include semiconductor materials having different polarities has been described above as an example; however, the disclosure is not limited thereto. That is, in the semiconductor device 200 illustrated in FIG. 5, the first and second two-dimensional material layers 221 and 222 may include semiconductor materials having the same polarity.

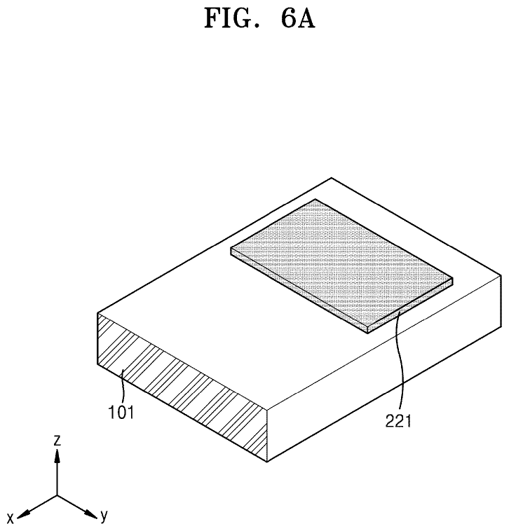

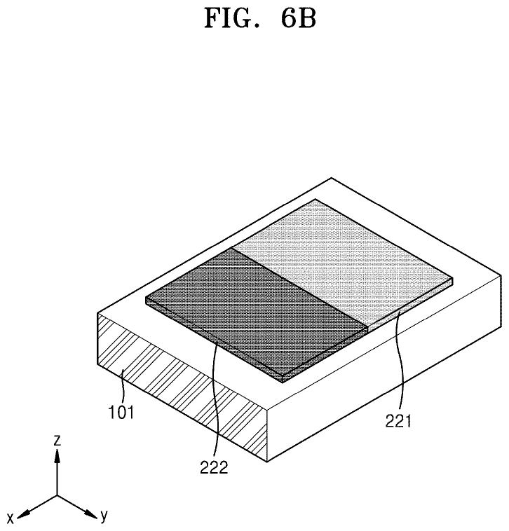

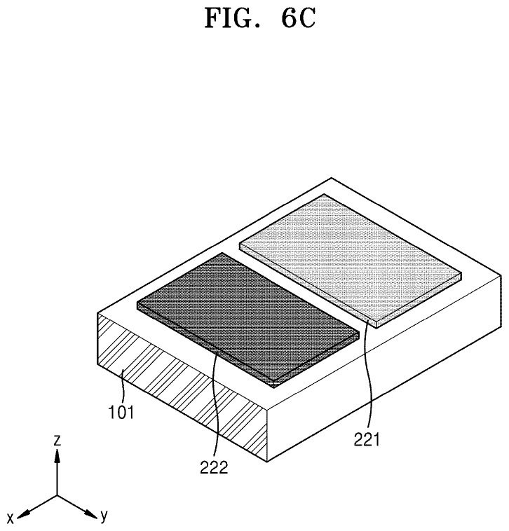

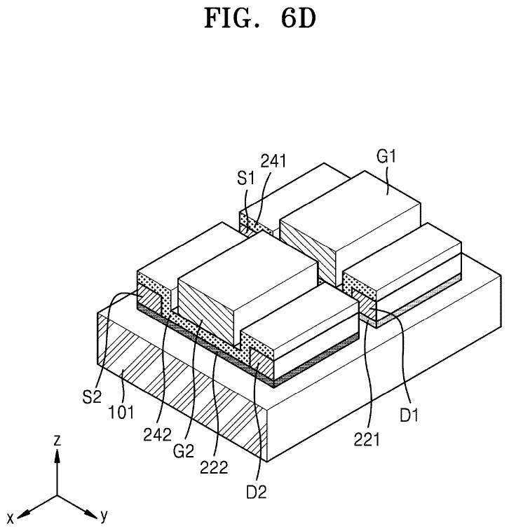

FIGS. 6A to 6D illustrate a method of manufacturing the semiconductor device 200, according to an embodiment.

Referring to FIG. 6A, a first two-dimensional material layer 221 may be formed on the upper surface of a substrate 101. The first two-dimensional material layer 221 may be formed by growing a first two-dimensional material on the upper surface of the substrate 101 by using, for example, CVD (e.g., MOCVD) and then patterning the first two-dimensional material into a certain shape. The first two-dimensional material layer 221 may have a length in the first direction (y-axis direction) and a width in the second direction (x-axis direction). The patterned first two-dimensional material forming the first two-dimensional material layer 221 may have a monocrystalline structure with a certain crystal orientation.

The first two-dimensional material may include a semiconductor material having a bandgap of about 0.1 eV to about 3.0 eV. For example, the first two-dimensional material may include TMD, black phosphorus, or graphene. The first two-dimensional material layer 221 may include, for example, about 1 layer to about 10 layers (e.g., about 1 layer to about 5 layers); however, the disclosure is not limited thereto.

Referring to FIG. 6B, a second two-dimensional material layer 222 junctioned to the side surface of the first two-dimensional material layer 221 may be formed on the upper surface of the substrate 101. Here, the side surface of the first two-dimensional material layer 221 to which the second two-dimensional material layer 222 is junctioned may be parallel to the first direction (y-axis direction). The second two-dimensional material layer 222 may be formed by lateral-epitaxial-growing a second two-dimensional material from a patterned edge of the first two-dimensional material layer 221 by using CVD (e.g., MOCVD). An operation of patterning the second two-dimensional material into a certain shape after growing the second two-dimensional material may be further included. Here, the second two-dimensional material may have a lattice constant similar to a lattice constant of the first two-dimensional material. For example, a lattice constant difference between the first two-dimensional material and the second two-dimensional material may be about 10% or less. The second two-dimensional material may include a semiconductor material having a bandgap of about 0.1 eV to about 3.0 eV. For example, the first two-dimensional material may include TMD, black phosphorus, or graphene. The second two-dimensional material layer 222 may include, for example, about 1 layer to about 10 layers (e.g., about 1 layer to about 5 layers); however, the disclosure is not limited thereto.

By controlling growth conditions (e.g., the flow rate of a precursor material, the injection amount of the carrier gas, the reaction temperature, the pressure, and/or the like) in the growing process of the second two-dimensional material, the second two-dimensional material having the same crystal orientation as the first two-dimensional material may be grown on the side surface of the first two-dimensional material layer 221. The second two-dimensional material forming the second two-dimensional material layer 222 may include a monocrystalline structure having the same crystal orientation as the first two-dimensional material. Thus, the first two-dimensional material layer 221 and the second two-dimensional material layer 222 may be hetero-junctioned to each other to form a coherent interface having almost no defects.

The first and second two-dimensional material layers 221 and 222 may include semiconductor materials having different polarities. For example, the first two-dimensional material layer 221 may include an n-type semiconductor material, and the second two-dimensional material layer 222 may include a p-type semiconductor material. Also, the first two-dimensional material layer 221 may include a p-type semiconductor material, and the second two-dimensional material layer 222 may include an n-type semiconductor material. Alternatively, the first and second two-dimensional material layers 221 and 222 may include semiconductor materials having the same polarity.

The first and second two-dimensional material layers 221 and 222 may have the same length and width. However, the disclosure is not limited thereto, and the first and second two-dimensional material layers 221 and 222 may be configured such that at least one of lengths and widths thereof are different from each other.

Referring to FIG. 6C, the junction area between the first and second two-dimensional material layers 221 and 222 may be removed through patterning. Accordingly, the first and second two-dimensional material layers 221 and 222 may be arranged apart from each other in the second direction (x-axis direction).

Referring to FIG. 6D, a first source electrode S1 and a first drain electrode D1 may be formed on both sides of the first two-dimensional material layer 221 respectively. Also, a first gate insulating layer 241 and a first gate electrode G1 may be sequentially formed on the first two-dimensional material layer 221 between the first source electrode S1 and the first drain electrode D1. A second source electrode S2 and a second drain electrode D2 may be formed on both sides of the second two-dimensional material layer 222 respectively. Also, a second gate insulating layer 242 and a second gate electrode G2 may be sequentially formed on the second two-dimensional material layer 222 between the second source electrode S2 and the second drain electrode D2.

The first and second source electrodes S1 and S2 and the first and second drain electrodes D1 and D2 may include, for example, a metal material with excellent electrical conductivity such as Ag, Au, Pt, or Cu; however, the disclosure is not limited thereto. The first and second gate insulating layers 241,242 may include, for example, a silicon nitride; however, the disclosure is not limited thereto. Each of the first and second gate electrodes G1 and G2 may include a metal material or a conductive oxide.

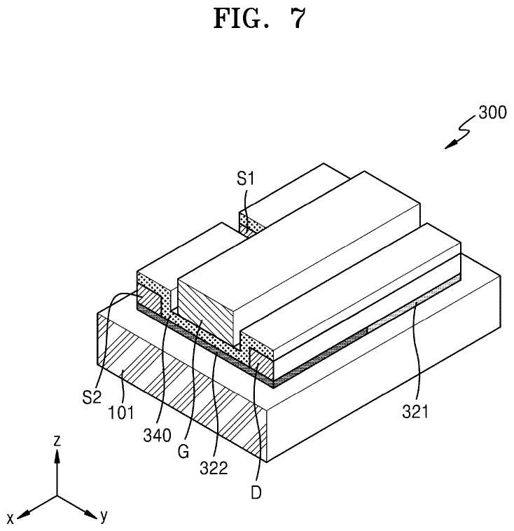

FIG. 7 is a perspective view illustrating a semiconductor device 300 according to another embodiment. The semiconductor device 300 illustrated in FIG. 7 may include a CMOS inverter. Hereinafter, differences from the above embodiments will be mainly described.

Referring to FIG. 7, first and second two-dimensional material layers 321 and 322 junctioned to each other may be arranged on a substrate 101. The first and second two-dimensional material layers 321 and 322 may be hetero-junctioned to each other in the lateral direction to form a coherent interface therebetween. The junction interface between the first and second two-dimensional material layers 321 and 322 may be parallel to a certain direction (y-axis direction).

A first two-dimensional material constituting the first two-dimensional material layer 321 may include a monocrystalline structure having a certain crystal orientation, and a second two-dimensional material constituting the second two-dimensional material layer 322 may include a monocrystalline structure having the same crystal orientation as the first two-dimensional material. Because the first and second two-dimensional materials have been described above, redundant descriptions thereof will be omitted for conciseness.

A first source electrode S1 and a drain electrode D may be arranged on both sides of the first two-dimensional material layer 321, and a second source electrode S2 and a drain electrode D may be arranged on both sides of the second two-dimensional material layer 322. Here, the drain electrode D may be a common drain electrode and may be arranged on a junction area between the first and second two-dimensional material layers 321 and 322.

The first source electrode S1 and the drain electrode D may be arranged apart from each other in the longitudinal direction (y-axis direction) of the first two-dimensional material layer 321. The first two-dimensional material layer 321 may form a first channel between the first source electrode S1 and the drain electrode D. The second source electrode S2 and the drain electrode D may be arranged apart from each other in the longitudinal direction (y-axis direction) of the second two-dimensional material layer 322. The second two-dimensional material layer 322 may form a second channel between the second source electrode S2 and the drain electrode D. A gate insulating layer 340 and a gate electrode G may be sequentially arranged on the first and second two-dimensional material layers 321 and 322 between the first and second source electrodes S1 and S2 and the drain electrode D. Here, the gate electrode G may be a common gate electrode.

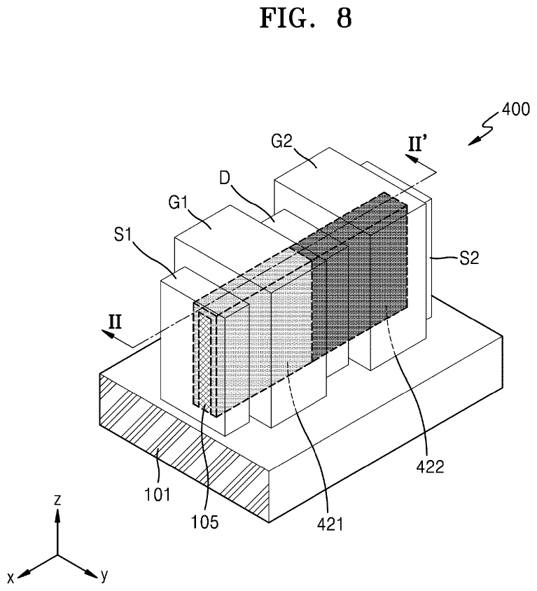

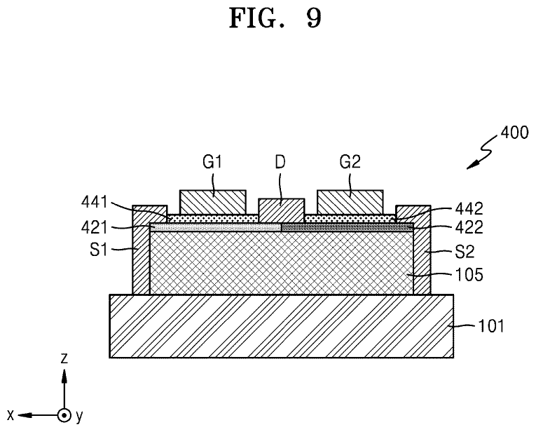

FIG. 8 is a perspective view illustrating a semiconductor device 400 according to another embodiment. FIG. 9 is a cross-sectional view taken along line II-II′ of FIG. 8.

Referring to FIGS. 8 and 9, on a substrate 101, an insulator 105 may be arranged perpendicular to the substrate 101, and first and second two-dimensional material layers 421 and 422 junctioned to each other may be arranged on the insulator 105. The first and second two-dimensional material layers 421 and 422 may be arranged to surround three surfaces of the insulator 105. The first two-dimensional material layer 421 and the second two-dimensional material layer 422 may be junctioned to each other to form a coherent interface having almost no defects.

The first and second two-dimensional material layers 421 and 422 may be hetero-junctioned to each other in the lateral direction to form a coherent interface therebetween. Each of the first and second two-dimensional material layers 421 and 422 may include a two-dimensional material having semiconductor characteristics.

The first two-dimensional material layer 421 may include a first two-dimensional material having a monocrystalline structure having a certain crystal orientation, and the second two-dimensional material layer 422 may include a second two-dimensional material having a monocrystalline structure having the same crystal orientation as the first two-dimensional material. Because the first and second two-dimensional materials have been described above, redundant descriptions thereof will be omitted for conciseness.

The first two-dimensional material layer 421 may be formed by growing a first two-dimensional material on the surface of the insulator 105 and then patterning the first two-dimensional material. The second two-dimensional material layer 422 may be formed by lateral-epitaxial-growing a second two-dimensional material from a patterned edge of the first two-dimensional material layer 421. Here, the second two-dimensional material constituting the second two-dimensional material layer 422 may include a monocrystalline structure having the same crystal orientation as the first two-dimensional material. Accordingly, the first two-dimensional material layer 421 and the second two-dimensional material layer 422 may be junctioned to each other to form a coherent interface having almost no defects.

A first source electrode S1 and a drain electrode D may be arranged on both sides of the first two-dimensional material layer 421, and a second source electrode S2 and a drain electrode D may be arranged on both sides of the second two-dimensional material layer 422. Here, the drain electrode D may be a common drain electrode and may be arranged on a junction area between the first and second two-dimensional material layers 421 and 422.

The first source electrode S1 and the drain electrode D may be arranged apart from each other in the longitudinal direction (x-axis direction) of the first two-dimensional material layer 421. The first two-dimensional material layer 421 may form a first channel between the first source electrode S1 and the drain electrode D. The second source electrode S2 and the drain electrode D may be arranged apart from each other in the longitudinal direction (x-axis direction) of the second two-dimensional material layer 422. The second two-dimensional material layer 422 may form a second channel between the second source electrode S2 and the drain electrode D.

A first gate insulating layer 441 and a first gate electrode G1 may be sequentially arranged on the first two-dimensional material layer 421 between the first source electrode S1 and the drain electrode D. Also, a second gate insulating layer 442 and a second gate electrode G2 may be sequentially arranged on the second two-dimensional material layer 422 between the second source electrode S2 and the drain electrode D. The first and second gate electrodes G1 and G2 may be configured to be electrically connected to each other such that the same voltage may be applied thereto.

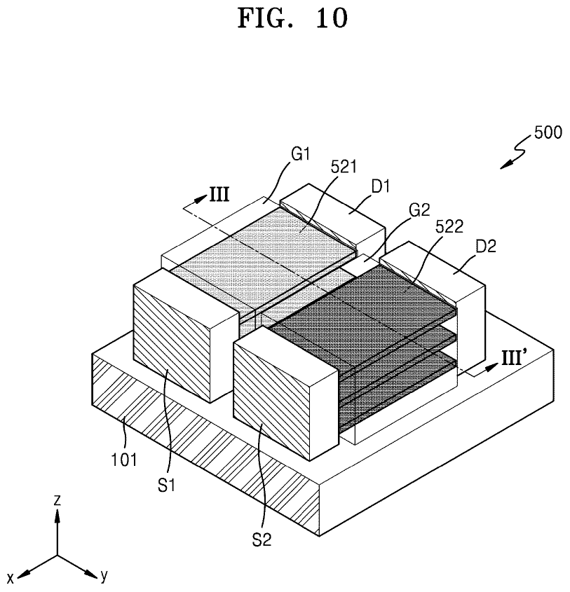

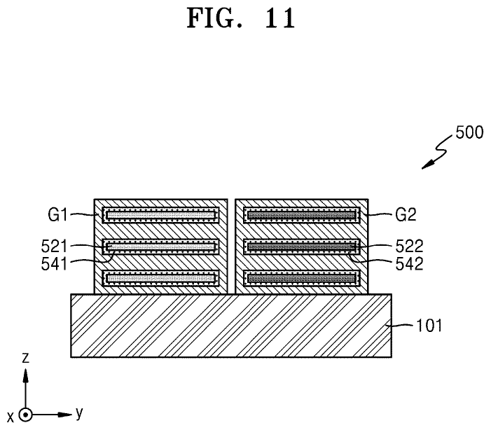

FIG. 10 is a perspective view illustrating a semiconductor device 500 according to another embodiment. FIG. 11 is a cross-sectional view taken along line III-III′ of FIG. 10.

Referring to FIGS. 10 and 11, on a substrate 101, a plurality of first two-dimensional material layers 521 and a plurality of second two-dimensional material layers 522 may be arranged parallel to the upper surface of the substrate 101. The first two-dimensional material layers 521 may be spaced apart from each other in a direction (z-axis direction) perpendicular to the upper surface of the substrate 101, and the second two-dimensional material layers 522 may be spaced apart from each other in a direction (z-axis direction) perpendicular to the upper surface of the substrate 101. Each first two-dimensional material layer 521 and each second two-dimensional material layer 522 may be spaced apart from each other in a certain direction (y-axis direction).

The first two-dimensional material layers 521 may include a first two-dimensional material having a monocrystalline structure having a certain crystal orientation, and the second two-dimensional material layers 522 may include a second two-dimensional material having a monocrystalline structure having the same crystal orientation as the first two-dimensional material. Because the first and second two-dimensional materials have been described above, redundant descriptions thereof will be omitted for conciseness.

Each first two-dimensional material layer 521 may be formed by growing a first two-dimensional material on the surface of a certain material layer (not illustrated) and then patterning the first two-dimensional material, and each second two-dimensional material layer 522 may be formed by lateral-epitaxial-growing a second two-dimensional material from a patterned edge of each first two-dimensional material layer 521. Here, the second two-dimensional material may include a monocrystalline structure having the same crystal orientation as the first two-dimensional material. Subsequently, first and second two-dimensional material layers 521 and 522 spaced apart from each other and having a monocrystalline structure with the same crystal orientation may be formed by removing the junction area between the first and second two-dimensional material layers 521 and 522 by patterning.

A first source electrode S1 and a first drain electrode D1 may be arranged on both sides of the first two-dimensional material layers 521, and a second source electrode S2 and a second drain electrode D2 may be arranged on both sides of the second two-dimensional material layers 522. The first source electrode S1 and the first drain electrode D1 may be arranged apart from each other in the longitudinal direction (x-axis direction) of the first two-dimensional material layers 521. The second source electrode S2 and the second drain electrode D2 may be arranged apart from each other in the longitudinal direction (x-axis direction) of the second two-dimensional material layer 522.

A first gate insulating layer 541 may be arranged to surround the first two-dimensional material layers 521 between the first source electrode S1 and the first drain electrode D1, and a first gate electrode G1 may be arranged to surround the first gate insulating layer 541. Also, a second gate insulating layer 542 may be arranged to surround the second two-dimensional material layers 522 between the second source electrode S2 and the second drain electrode D2, and a second gate electrode G2 may be arranged to surround the second gate insulating layer 542.

A case where the first two-dimensional material layers 521 and the second two-dimensional material layers 522 include semiconductor materials having different polarities has been described above as an example; however, the disclosure is not limited thereto. That is, the first two-dimensional material layers 521 and the second two-dimensional material layers 522 may also include semiconductor materials having the same polarity.

According to the above embodiments, because the first and second two-dimensional material layers having a monocrystalline structure are hetero-junctioned to each other in the lateral direction to form a coherent interface, the degradation of electron transfer due to a grain boundary may be limited and/or prevented and thus the high-performance semiconductor device may be implemented. Although embodiments have been described above, the embodiments are merely examples and various modifications may be made therein by those of ordinary skill in the art.

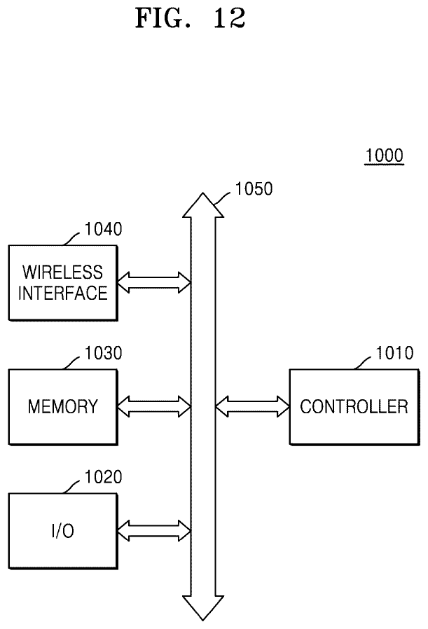

Semiconductor devices according to example embodiments may be applied to an electronic system. For example, FIG. 12 is a block diagram of an electronic system including an semiconductor device according to an embodiment.

The electronic system 1000 may be a wireless communication device or a device capable of transmitting and/or receiving information in a wireless environment.

The electronic system 1000 includes a controller 1010, an input/output device (I/O) 1020, a memory 1030, and a wireless interface 1040, and these components are interconnected to each other through a bus 1050.

The controller 1010 may include at least one of a microprocessor, a digital signal processor, or a processing device similar thereto. The input/output device 1020 may include at least one of a keypad, a keyboard, and a display (e.g., LCD display, OLED display). The memory 1030 may be used to store instructions executed by controller 1010. For example, the memory 1030 may be used to store user data. The electronic system 1000 may use the wireless interface 1040 to transmit/receive data through a wireless communication network. The wireless interface 1040 may include an antenna and/or a wireless transceiver. In some embodiments, the electronic system 1000 may be used in a communication interface protocol of a variety of communication systems, for example, code division multiple access (CDMA), global system for mobile communications (GSM), north American digital cellular (NADC), extended-time division multiple access (E-TDMA), and/or wide band code division multiple access (WCDMA). The electronic system 1000, for example in the controller 1010, input/output device 1020, memory 1030, and/or wireless interface 1040, may include any one of the semiconductor devices 100, 200, 300, 400, and 500 described above.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a substrate;
a first two-dimensional material layer and a second two-dimensional material layer on the substrate, the first two-dimensional material layer and the second two-dimensional material layer being junctioned to each other in a lateral direction to form a coherent interface;
a first source electrode and a first drain electrode on the first two-dimensional material layer;
a first gate electrode between the first source electrode and the first drain electrode;
a second source electrode and a second drain electrode on the second two-dimensional material layer; and
a second gate electrode between the second source electrode and the second drain electrode.

2. The semiconductor device of claim 1, wherein
the first two-dimensional material layer and the second two-dimensional material layer have monocrystalline structures with a same crystal orientation, and
a material of the first two-dimensional material layer is different than a material of the second two-dimensional material layer.

3. The semiconductor device of claim 1, wherein a lattice constant difference between a material of the first two-dimensional material layer and a material of the second two-dimensional material layer is 10% or less.

4. The semiconductor device of claim 1, wherein
a semiconductor material of the first two-dimensional material layer and a semiconductor material of the second two-dimensional material layer each have a bandgap of about 0.1 eV to about 3.0 eV.

5. The semiconductor device of claim 1, wherein
the first two-dimensional material layer and the second two-dimensional material layer each independently comprise transition metal dichalcogenide (TMD), black phosphorus, or graphene.

6. The semiconductor device of claim 5, wherein
the first two-dimensional material layer, the second two-dimensional material layer, or both the first two-dimensional material layer and the second two-dimensional material layer include the TMD,
the TMD comprises a metal element and a chalcogen element,
the metal element includes one of Mo, W, Nb, V, Ta, Ti, Zr, Hf, Tc, and Re, and
the chalcogen element includes one of S, Se, and Te.

7. The semiconductor device of claim 1, wherein the first two-dimensional material layer and the second two-dimensional material layer each comprise about 1 layer to about 10 layers.

8. The semiconductor device of claim 1, further comprising:
a first gate insulating layer between the first two-dimensional material layer and the first gate electrode; and
a second gate insulating layer between the second two-dimensional material layer and the second gate electrode.

9. The semiconductor device of claim 1, wherein
a first one of the first two-dimensional material layer and the second two-dimensional material layer comprises an n-type semiconductor material, and
a second one of the first two-dimensional material layer and second two-dimensional material layer comprises a p-type semiconductor material.

10. The semiconductor device of claim 9, wherein
the first two-dimensional material layer, the second two-dimensional material layer, the first source electrode, the first drain electrode, the second source electrode, the second drain electrode, the first gate electrode, and the second gate electrode are parts of a complementary metal-oxide-semiconductor (CMOS) inverter.

11. The semiconductor device of claim 10, wherein
the first drain electrode and the second drain electrode are integrally formed to provide a common drain electrode.

12. The semiconductor device of claim 11, wherein the common drain electrode is on a junction area between the first two-dimensional material layer and the second two-dimensional material layer.

13. The semiconductor device of claim 10, wherein the first gate electrode and the second gate electrode are electrically connected to each other.

14. The semiconductor device of claim 10, wherein the first gate electrode and the second gate electrodes are integrally formed to constitute a common gate electrode.

15. A method of manufacturing a semiconductor device, the method comprising:
forming a first two-dimensional material layer by depositing a first two-dimensional material on a substrate and patterning the first two-dimensional material;
forming a second two-dimensional material layer by lateral-epitaxial-growing a second two-dimensional material at a patterned edge of the first two-dimensional material layer, the second two-dimensional material layer forming a coherent interface with the first two-dimensional material layer,
the first two-dimensional material layer and the second two-dimensional material layer each having a monocrystalline structure;
forming a first source electrode and a first drain electrode on the first two-dimensional material layer;
forming a first gate electrode between the first source electrode and the first drain electrode;
forming a second source electrode and a second drain electrode on the second two-dimensional material layer; and
forming a second gate electrode between the second source electrode and the second drain electrode.

16. The method of claim 15, wherein the first two-dimensional material layer and the second two-dimensional material layer each independently comprise transition metal dichalcogenide (TMD), black phosphorus, or graphene.

17. The method of claim 15, wherein
a first one of the first two-dimensional material layer and the second two-dimensional material layer comprises an n-type semiconductor material, and
a second one of the first two-dimensional material layer and the second two-dimensional material layer comprises an p-type semiconductor material.

18. The method of claim 16, wherein the first drain electrode and the second drain electrode are integrally formed to constitute a common drain electrode.

19. The method of claim 18, wherein the common drain electrode is formed on a junction area between the first two-dimensional material layer and the second two-dimensional material layer.

20. The method of claim 16, wherein the first gate electrode and the second gate electrode are integrally formed to constitute a common gate electrode.
